(19) United States
(12) Patent Application Publication
(10) Pub. No.: US 2026/0225353 A1
(43) Pub. Date: Aug. 6, 2026

(54) WINDOW WITH SEALANT CONTAINING QUANTUM DOTS

(71) Applicant: Dow Silicones Corporation, Midland, MI (US)

(72) Inventors: James A. Casey, Midland, MI (US); David Witker, Midland, MI (US)

(21) Appl. No.: 19/151,367

(22) PCT Filed: Feb. 1, 2024
(86) PCT No.: PCT/US2024/013990

§ 371 Date: Jul. 28, 2025

Related U.S. Application Data
(60) Provisional application No. 63/444,595, filed on Feb. 10, 2023.

(51) Int. Cl. B32B 17/10; B32B 3/04

(52) U.S. Cl. CPC B32B 17/10669; B32B 3/04; B32B 17/10036; B32B 17/10302; B32B 17/10541; B32B 2419/00; B32B 2457/12

(57) ABSTRACT

An article includes: (a) a windowpane having opposing primary surfaces and edges extending around the primary surfaces; (b) a window frame that resides around at least a portion of the edges of the windowpane; and (c) a sealant in light-transmitting contact with an edge of the windowpane; wherein the sealant contains quantum dots.

### FIELD OF THE INVENTION

The present invention relates to window articles that comprise sealant containing quantum dots.

### INTRODUCTION

Solar energy is one source of sustainable “clean” energy that continues to grow in interest and application. Harvesting solar energy typically requires positioning solar cells that convert light to electrical energy in such a way that sunlight shines on those solar cells. Positioning solar cells on building roofs or in open fields is a common practice for harvesting solar energy to optimize exposure of the solar cells to sunlight.

Harvesting solar energy becomes more challenging when there are obstacles to sunlight exposure. For instance, buildings in urban settings such as large cities typically have other buildings inhibiting sunlight exposure. Similarly, forested locations have trees inhibiting sunlight exposure making solar harvesting difficult for homes and buildings in forested locations. It would be helpful in the effort of harvesting solar energy, particularly in settings such as urban settings and forested locations, if there was a way to concentrate sunlight that does reach a building. Even better would be a way to direct that concentrated sunlight, onto solar cells. Yet even more desirable is if such a means could direct and focus onto solar cells those wavelengths of sunlight that solar cells most efficiently convert to electrical energy.

Luminescent solar concentrators are one technology developed for such applications. See, for example, Moraitis et al., Opt. Mater. 2018, 84, 636-645 for an example of one review of this technology. Yet, there is still room for improving luminescent solar concentrator technology in window applications.

### BRIEF SUMMARY OF THE INVENTION

The present invention provides a solution to the problem of providing improvements over luminescent solar concentrator technology as it applies to window applications.

The present invention is a result of discovering that quantum dots can reside in the sealant of a window article. Quantum dots in the sealant of a window article can absorb light and convert that light into wavelengths usable by solar cells to convert the light into electrical energy. Advantageously, quantum dots in the sealant of a window do not reside in the viewing plane of a window and, as a result, do not impact the view through a window. One drawback to incorporating quantum dots into a window is that they tend to impact visibility through the window. Putting quantum dots into the sealant around a windowpane places the quantum dots out of the viewing plane of the window and thereby obviates impact on viewing through the window. Nonetheless, the quantum dots in the sealant can still absorb and convert that light to electrical energy. Particularly advantageous is the fact that quantum dots in the sealant can convert light that otherwise might be lost by escaping a windowpane through its edges. Moreover, quantum dots in window sealant can be used in combination with quantum dots in other locations of a window structure, including the viewing plane, to increase the amount of light incident on the window that can be converted to electrical energy.

In a first aspect, the present invention is an article comprising: (a) a windowpane having opposing primary surfaces and edges extending around the primary surfaces; (b) a window frame that resides around at least a portion of the edges of the windowpane; and (c) a sealant in light-transmitting contact with an edge of the windowpane; wherein the sealant comprises quantum dots.

Articles of the present invention are useful as windows in structures that convert incident light into electrical energy.

### BRIEF DESCRIPTION OF DRAWINGS

FIG. 1(a) presents a face-on view of an article of the present invention viewing into the primary surface of a windowpane of the article.

FIG. 1(b) presents a side view of an embodiment of the article of FIG. 1(a) as viewed along viewing line A and with a portion of the window frame 20 cut away.

FIG. 1(c) presents a side view of an embodiment of the article of FIG. 1(a) that comprises reflective material as viewed along viewing line A and with a portion of the window frame 20 cut away.

### DETAILED DESCRIPTION OF THE INVENTION

Products identified by their tradename refer to the compositions available under those tradenames on the priority date of this document.

“Multiple” means two or more. “And/or” means “and, or as an alternative”. All ranges include endpoints unless otherwise indicated.

“Cx to Cy”, “Cₓ-C_{y}”, “C_{x-y}” are interchangeable and refer to a composition having a number of carbon atoms in a range of from x to y.

“Silicon nanoparticle” refers to a silicon-based particle having an average particle size of less than one micrometer, typically a particle size of 100 nanometers (nm) or less, while at the same time having an average particle size of one or more than one nm. Dynamic light scattering or transmission electron microscopy image analysis are common ways to determine average particle size for silicon nanoparticles. Silicon nanoparticles include silicon quantum dots.

“Silicon-based” refers to a composition comprising silicon. A silicon-based material generally contains 40 percent (%) or more, and can contain 50 % or more, 60 % or more, 70% or more, 80 % or more, 90% or more, even 100 % silicon atoms or a combination of silicon and oxygen atoms based relative to all atoms in the material.

“Quantum dots” refer to nanoscale particles that transport electrons and, when irradiated with photons having a higher energy than the bandgap of the quantum dot material emit light of various wavelengths depending on the properties of the particles.

“Silicon quantum dots” (“SiQDs”) refer to silicon nanoparticles that have a crystalline silicon structure and that photoluminesces when exposed to light. Typically, SiQDs have an average particle size that is in a range of one to 10 nanometers, preferably in a range of one to 6 nanometers, more preferably in a range of one to 5 nanometers. Silicon quantum dots are characterized by the fact that they luminesce when exposed to light having a wavelength in a wavelength range of 300 to 477 nanometers, corresponding to blue and ultraviolet light.

Unless specifically stated otherwise in the context of use, “quantum dots” as used herein refers to any type of quantum dots including SiQDs.

“Solar cell” is a term that is interchangeable with photovoltaic cell and refers to an electronic device that converts the energy of light into electricity by a physical and chemical phenomenon known as the photovoltaic effect.

“Windowpane” refers to that portion of a window that serves to block wind and environmental elements such as rain, dust, and pests from penetrating through a window while typically allowing light to penetrate through the window. The windowpane comprises at least one sheet of windowpane material. Desirably, the windowpane is made of one or more than one sheet of glass.

“Primary surface” refers to a surface having the highest planar surface area of any surface of an article and the surface opposing that surface if there is such an opposing surface. “Planar surface area” refers to the surface area as projected onto a plane in order to preclude accounting for holes, pits, valleys or other contours of the surface. “Edge” of an article with opposing primary surfaces refers to the surface(s) separating the opposing primary surfaces and extending around the perimeter of the primary surfaces.

“Light-transmitting contact” refers to direct or indirect contact between two or more elements, wherein the contact allows light to transmit from one element to another.

“Vacuum” as used herein refers to an atmosphere at a pressure below atmospheric pressure around the environment described as having a vacuum. For example, a window with a vacuum between two windowpanes refers to a window with a pressure between the two windowpanes that is lower than the pressure of the atmosphere around the window. Typically, a vacuum has a pressure below 101 kiloPascals (kPa) and can be 50 kPa or less, 20 kPa or less, 10 kPa or less, 5 kPa or less, one kPa or less, even 0.1 kPa or less.

The present invention is an article comprising: (a) a windowpane having opposing primary surfaces and edges extending around the primary surfaces; (b) a window frame that resides around at least a portion of the edges of the windowpane; and (c) a sealant between at the windowpane and window frame; wherein the sealant comprises SiQDs.

### Windowpane

The article of the present invention can comprise a single windowpane or multiple windowpanes each having opposing primary surfaces and edges extending around their primary surfaces. In the broadest scope of the present invention, there is no limit as to the windowpane material though it desirably allows visible light transmission through it. When there are multiple windowpanes, the windowpanes can be the same material or can differ in material. Examples of suitable windowpane material includes those comprising glass, polymers (such as organic polymers) or a combination of glass and polymers. Glass includes silicate glasses such as soda-lime-silica glasses, borosilicate glasses. Polymers suitable for use as windowpanes include organic polymers such as polymethylmethacrylate (PMMA) and polycarbonate.

A windowpane can comprise quantum dots on and/or in the windowpane. For example, a polymeric windowpane can be a polymer film with quantum dots dispersed within the film or coated on a surface of the film. Gallagher et al, Sol. Energy 2007, 81, 813-821 describes quantum dot solar concentrators suitable for use as windowpanes that have quantum dots dispersed in polyurethane or PMMA sheets. A windowpane can have quantum dots adhered to a surface of the windowpane either directly or as a polymeric film or coating comprising quantum dots that is adhered to the windowpane surface.

The article of the present invention can comprise laminated glass as one or more than one windowpane. Laminated glass comprises glass sheets that have a primary surface of each laminated to one another with a polymeric film between the glass sheets. Laminated glass can be in the form of “safety glass”. Common polymer films between glass sheets include ethylvinyl acetate (EVA), polyvinyl butyral (PVB), and ionomers. The laminated glass can comprise quantum dots. For example, the polymer film between the glass sheets of laminated glass can comprise quantum dots. For example, US2017/0341346 discloses laminated glass luminescent concentrators with certain types of quantum dots in the polymeric film between the glass sheets of the laminated glass and such laminated glass is suitable for use as a windowpane in the present invention. In particular, the present invention can comprise a laminated glass with SiQDs in or on the polymeric film between the glass sheets of the laminated glass. SiQDs are particularly desirable in such an application due to their temperature stability, which allows them to be included in processes using lamination at temperatures above temperatures where other quantum dots would degrade.

The article of the present invention can be a thermally insulated window comprising two or more windowpanes separated from one another to define a volume between them that is sealed and that has in the volume between them a vacuum or insulating gas. The vacuum or insulating gas inhibits thermal conductivity through the windowpanes. Examples of suitable thermally insulating gas includes any one or combination of noble gases, such as those selected from a group consisting of argon, krypton and xenon. The thermally insulated window can comprise quantum dots, including SiQDs. Quantum dots can reside within one or more windowpane of the thermally insulated window. Quantum dots can reside on a surface of one or more windowpane of the thermally insulated window, preferably on a surface in contact with the volume under vacuum or containing insulating gas. Quantum dots can reside directly on a surface of a windowpane or reside in a polymeric film or coating on the surface of a windowpane.

The article of the present invention can comprise multiple windowpanes separated by muntins so as to have a grid or latticework appearance.

### Window Frame

The article of the present invention has a window frame. The window frame holds the windowpane or windowpanes of the article in place. The window frame resides around at least a portion of the edges of the windowpane of the article. If the article comprises multiple windowpanes, desirably the window frame extends around at least a portion of the edges of all of the windowpanes. Desirably, the window frame extends all the way around the edges of the windowpane(s). The window frame typically comprises side jambs as the vertical parts of the window frame forming the sides of a window frame and top and bottom rails forming the top and bottom of the window frame, respectively.

In the broadest scope of the present invention, the composition of the window from has no restrictions. Common materials useful for the window frame include wood, plastic, metal, or a combination thereof.

### Sealant

The article of the present invention comprises a sealant in light-transmitting contact with an edge of one or more than one windowpane. Sealants are useful for providing air-tight contact between a windowpane and a window frame or other element adjacent to a windowpane. Typically, the article of the present invention comprises a window frame extending all around a windowpane (or combination of windowpanes) with sealant residing and forming a seal between the windowpane(s) and the window frame. The sealant can reside between only a portion of the windowpane and a portion of the window frame or extend all the way around a windowpane and window frame.

In the broadest scope of the present invention, the sealant can be any sealant useful for sealing windows and includes window seal tape, rubber window seal, and caulks. Sealants can include silicone caulk, polyurethane caulks, acrylic latex caulks, and butyl rubber caulk. Of particular interest is silicone room temperature vulcanizing (RTV) sealant materials.

The sealant comprises quantum dots. The quantum dots are desirably dispersed within the sealant. Preferably, quantum dots are dispersed within the sealant and the sealant transmits (at least partially) UV and/or visible light. The quantum dots can be SiQDs, which offer greater thermal stability than many other quantum dots. Additionally, SiQDs tend to be especially compatible with silicone caulk compositions, which are one of the most desirable sealants for windows. Desirably, the sealant is a silicone caulk with SiQDs dispersed therein.

The concentration of quantum dots in the sealant is not critical to the broadest scope of the present invention. An objective of having quantum dots in the sealant is to capture UV and/or blue light that reflects within the and out the edges of the windowpane and converts that to light useable by a solar cell to generate electricity. Therefore, higher concentrations of quantum dots in the sealant are desirable. Typically, the concentration of quantum dots in the sealant is 0.1 weight-percent (wt %) or more, preferably, one wt % or more, 5 wt % or more, even 10 wt % or more while at the same time it is typically 30 wt % or less, 20 wt % or less, 15 wt % or less, and can be 10 wt % or less.

Quantum dots can be physically blended into sealant to obtain the sealant of the present invention. The quantum dots can be dispersed into a liquid carrier and blended with the sealant to facilitate mixing. Any mixing means is suitable including, for example, continuous methods such as extrusion mixing, as well as batch or semi-batch methods such as blender mixing.

### Solar Cell

Desirably, the article of the present invention comprises at least one and can comprise more than one solar cell in light-transmitting contact with an edge of a windowpane and/or sealant containing quantum dots.

When the solar cell is in light-transmitting contact with an edge of a windowpane, the sealant comprising quantum dots is also in light-transmitting contact with a portion of the edge of the windowpane. The solar cell collects light transmitted by the windowpane to the edges of the windowpane and converts that light to electricity. The quantum dots in the sealant desirably emit light at a wavelength convertible by the solar cell to electricity. In such a configuration, UV or blue light exiting the edge of a windowpane and impinging the sealant comprising quantum dots can be absorbed by the quantum dots in the sealant. The quantum dots can then emit light back into the edge of the windowpane and travel through the windowpane to a solar cell in light-transmitting contact with the edge of the windowpane. The light from the quantum dot can then be converted to electricity. Desirably, sealant with or without quantum dots in it provides a seal between the windowpane and window frame around solar cells in light-transmitting contact with the windowpane.

When the solar cell is in light-transmitting contact with the sealant then light emitted by the quantum dots in the sealant can emit onto the solar cell directly for conversion to electricity.

Examples of suitable solar cells include, for example, those made using monocrystalline silicon (m-Si), polycrystalline silicon, amorphous silicon, copper indium gallium selenide (CIGS), and cadmium telluride (CdTe) materials.

### Reflective Material

The article of the present invention can comprise a reflective material in light-transmitting contact with a portion of one or more edges of a windowpane. Reflective material can be desirable to reflect light that would otherwise be lost through the edge of a windowpane back into the windowpane. Lewo et al., J. Appl. Phys., 2013, 113, 214510 describes use of reflective panel edges to reduce loss of photons from a luminescent solar concentrators. Such an application of reflective material can apply to the present invention. Reflective material, if present, resides in light-transmitting contact with a portion of the edge of at least one windowpane of the article while the sealant also resides in light-transmitting contact with the windowpane. The article can comprise reflective material, sealant and at least one solar cell all in light-transmitting contact with an edge of a windowpane.

Examples of suitable reflective materials include metals such as aluminum, silver, and chrome, as well as compounds such as zinc sulfide and titanium dioxide.

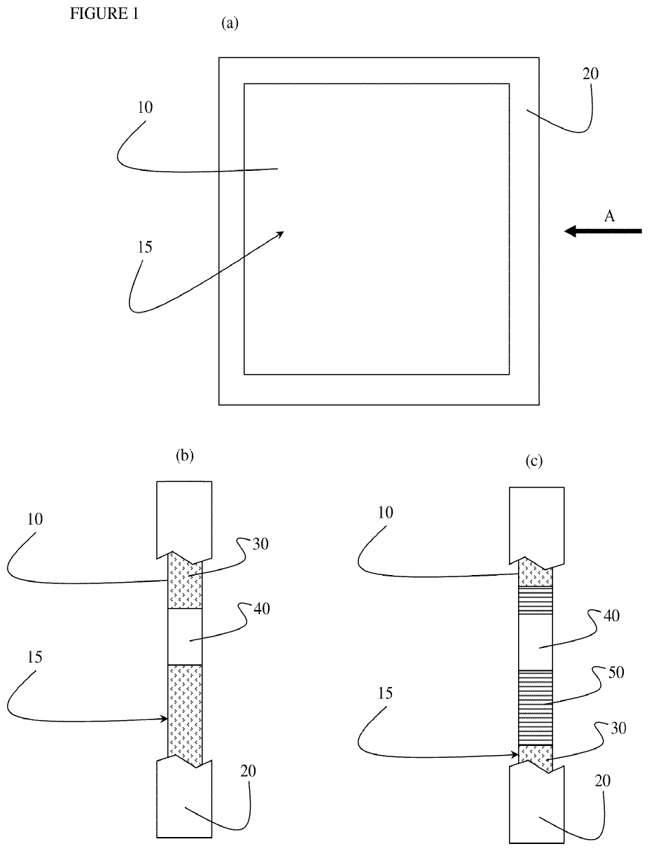

FIG. 1 shows an exemplary article of the present invention with windowpane 10 having primary surface 15, window frame 20 extending around the perimeter of windowpane 10. FIG. 1(a) shows the exemplary article facing a primary surface 15 of the windowpane 10. FIG. 1(b) and 1(c) show a side-view of two embodiments of the article in FIG. 1(a) as viewed along viewing line A. FIG. 1(b) shows an embodiment with sealant 30 on an edge of windowpane 10 and solar cell 40 also on an edge of windowpane 10. FIG. 1(c) shows an embodiment with sealant 30, solar cell 40 and reflective material 50 on an edge of windowpane 10. Sealant 30 has quantum dots dispersed therein (not shown).

1. An article comprising:
a. a windowpane having opposing primary surfaces and edges extending around the primary surfaces;
b. a window frame that resides around at least a portion of the edges of the windowpane; and
c. a sealant in light-transmitting contact with an edge of the windowpane; wherein the sealant comprises quantum dots.

2. The article of claim 1, wherein the article comprises multiple windowpanes each having opposition primary surfaces and edges extending around the primary surfaces and wherein the window frame resides around at least a portion of the edges of both windowpanes and the sealant is between one or both windowpanes and the window frame.

3. The article of claim 1, wherein the article further comprises a solar cell in light-transmitting contact with the sealant and/or at least one edge of at least one windowpane.

4. The article of claim 1, wherein the article comprises reflective material in light-transmitting contact with a portion of one or more edges of a windowpane.

5. The article of claim 1, wherein quantum dots are: (i) dispersed in at least one windowpane; and/or (ii) dispersed on and/or in a film or coating on a primary surface of a windowpane.

6. The article of claim 1, wherein the quantum dots are silicon quantum dots.

7. The article of claim 1, wherein the sealant is a silicone sealant with silicon quantum dots dispersed therein.

8. The article of claim 1, wherein the article comprises a laminated glass windowpane that has glass sheets laminated together with a polymeric film between the glass sheets, and that optionally comprises quantum dots in the polymeric film.

9. The article of claim 1, wherein the article comprises two or more windowpanes separated from one another to define a volume between them that is sealed and that has in the volume between them a vacuum or insulating gas, wherein the article optionally further comprises quantum dots in one or more of the windowpanes and/or on a surface of one or more of the windowpanes.
